(19) United States
(12) Patent Application Publication
(10) Pub. No.: US 2015/0171029 A1
(43) Pub. Date: Jun. 18, 2015

(54) INVERSE NANOSTRUCTURE DIELECTRIC LAYERS

(71) Applicants: David J. Michalak, Portland, OR (US); James M. Blackwell, Portland, OR (US); Arkaprabha Sengupta, Hillsboro, OR (US)

(72) Inventors: David J. Michalak, Portland, OR (US); James M. Blackwell, Portland, OR (US); Arkaprabha Sengupta, Hillsboro, OR (US)

(21) Appl. No.: 14/108,239

(22) Filed: Dec. 16, 2013

(51) Int. Cl. H01L 23/00; H01L 23/50; H01L 21/02

(52) U.S. Cl. CPC H01L 23/564; H01L 21/02203; H01L 21/02282; H01L 23/50

(57) ABSTRACT

Embodiments of the present disclosure describe dielectric layers and methods for their fabrication and use. In some embodiments, a dielectric layer may include a dielectric material and a plurality of pores, wherein the dielectric material is arranged in an inverse nanostructure arrangement around the plurality of pores. Other embodiments may be described and/or claimed.

### FIELD

Embodiments of the present disclosure generally relate to the field of electrical devices, and more particularly, to dielectric layers.

### BACKGROUND

In conventional integrated circuit (IC) technologies, dielectric materials having a dielectric constant of 2.0 and above are currently used to electrically insulate conductive layers. Efforts to develop and integrate materials having dielectric constants lower than 2.3 have typically resulted in materials that are too weak to withstand the chemical and mechanical forces exerted during IC device manufacturing. Consequently, the portfolio of conventional dielectric materials currently limits the achievable improvements in electrical and/or mechanical performance of IC devices.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIGS. 1A-1E are cross-sectional views of portions of various embodiments of a dielectric layer, in accordance with some embodiments.

FIGS. 2A-2E are cross-sectional views of portions of templates for fabricating various embodiments of a dielectric layer, in accordance with some embodiments.

FIGS. 3-12 are cross-sectional views of various operations in the fabrication of a dielectric layer, in accordance with some embodiments.

FIG. 13 is a flow diagram of a method of fabricating a dielectric layer, in accordance with some embodiments.

FIG. 14 is a cross-sectional view of a portion of an integrated circuit device including a dielectric layer, in accordance with some embodiments.

FIG. 15 is a block diagram of a computing device that may include a dielectric layer, in accordance with some embodiments.

### DETAILED DESCRIPTION

Embodiments of the present disclosure describe dielectric layers and methods for their fabrication and use. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, horizontal/vertical, above/below and the like. Such descriptions are merely used to facilitate the discussion and are not intended to restrict the application of embodiments described herein to any particular orientation. The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other.

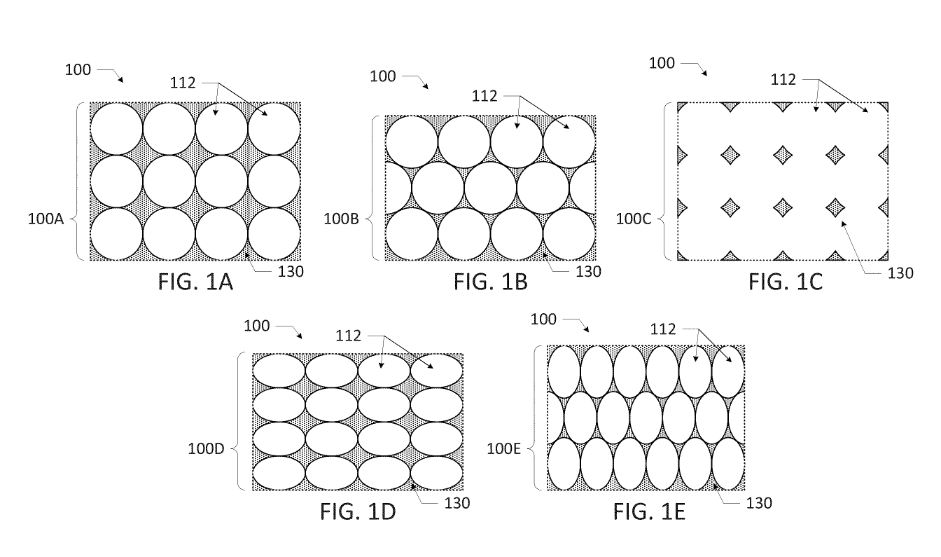

FIGS. 1A-1E are cross-sectional views of portions of various embodiments of a dielectric layer 100, in accordance with some embodiments. In some embodiments, the dielectric layer 100 may be used as or included in an interlayer dielectric (ILD) in an integrated circuit (IC) device. The dielectric layer 100 may include a dielectric material 130 and one or more pores 112. The pores 112 may provide voids in the dielectric material 130, and the dielectric material 130 may be arranged in an inverse nanostructure arrangement around the pores 112. As used herein, an “inverse nanostructure arrangement” may refer to a structure that is inverse to an arrangement of nanoparticles in the sense that the inverse nanostructure arrangement includes materials in the locations in which the arrangement of nanoparticles includes voids. A “pore” may refer to a void in an inverse nanostructure arrangement that corresponds to the location of a nanoparticle in the complementary nanostructure arrangement. By arranging the pores 112 in the dielectric layer 100 to correspond to the volume of a nanostructure taken up by nanoparticles, the dielectric layer 100 may be both highly porous and highly ordered. This ordering may allow the dielectric layer 100 to have a greater mechanical stiffness in one or more directions than dielectric materials having comparable porosities but with voids that are more randomly distributed, or dielectric materials that are semi-ordered or fully ordered into structures that provide less mechanical stiffness, as discussed in additional detail below.

In some embodiments, each of the individual pores of the pores 112 may have a common shape. For example, the pores 112 illustrated in FIGS. 1A-1C are all shaped substantially as nanospheres, while the pores 112 illustrated in FIGS. 1D and 1E are shaped as oblate and prolate spheroids, respectively. The pores 112 of the dielectric layer 100 may take the form of any suitable shape (e.g., shapes into which nanoparticles may be arranged), such as cylinders, tubes, spheres, spheroids, cubes, diamonds, tetrahedrons, hexahedrons, octahedrons or any other suitable shape. In some embodiments, different ones of the pores 112 in a particular dielectric layer 100 may have different shapes. For example, some of the pores 112 in a dielectric layer 100 may be spheres while others of the pores 112 may be prolate spheroids (not illustrated).

These pores 112 may be arranged in the dielectric material 130 in a regular pattern, corresponding to a nanostructure arrangement. This nanostructure arrangement may be an inverse opal arrangement, which may include a regular packing of pores shaped as nanospheres. For example, in some embodiments, the dielectric material 130 may be arranged as an inverse of a cubic-packed array of nanostructures (e.g., a cubic-packed array of nanospheres). Examples of such arrangements are illustrated in FIGS. 1A and 1D as the inverse nanosphere arrangement 100A and the inverse oblate nanospheroid arrangement 100D, respectively. In some embodiments, the dielectric material 130 may be arranged as an inverse of a hexagonally packed array of nanostructures (e.g., a hexagonally packed array of nanospheres in either an ABAB or ABCABC structure). Examples of certain hexagonal packing arrangement are illustrated in FIGS. 1B and 1E as the inverse nanosphere arrangement 100B and the inverse prolate nanospheroid arrangement 100E, respectively.

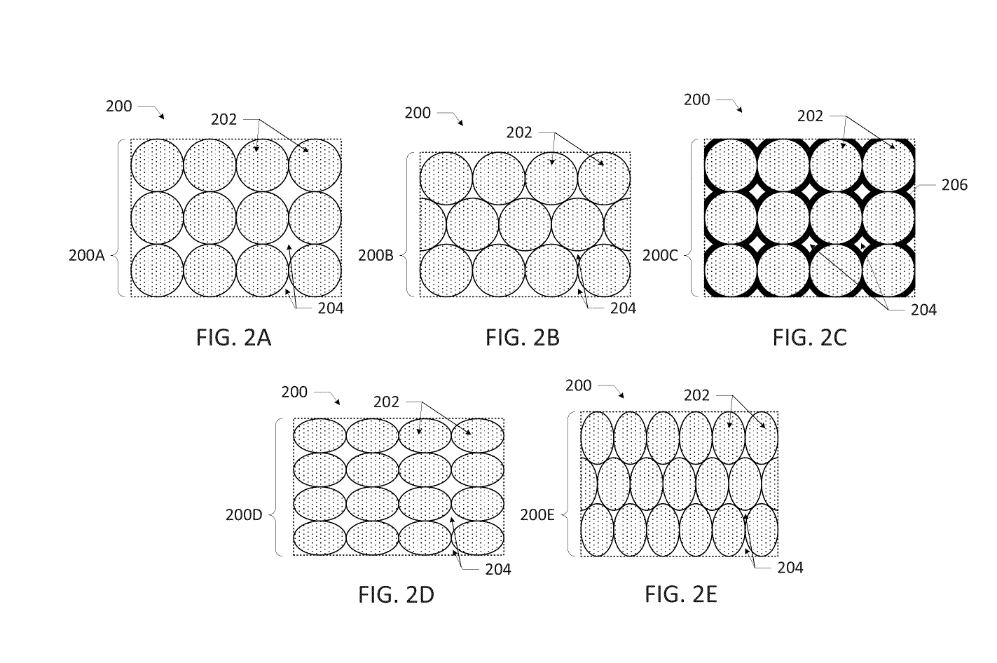

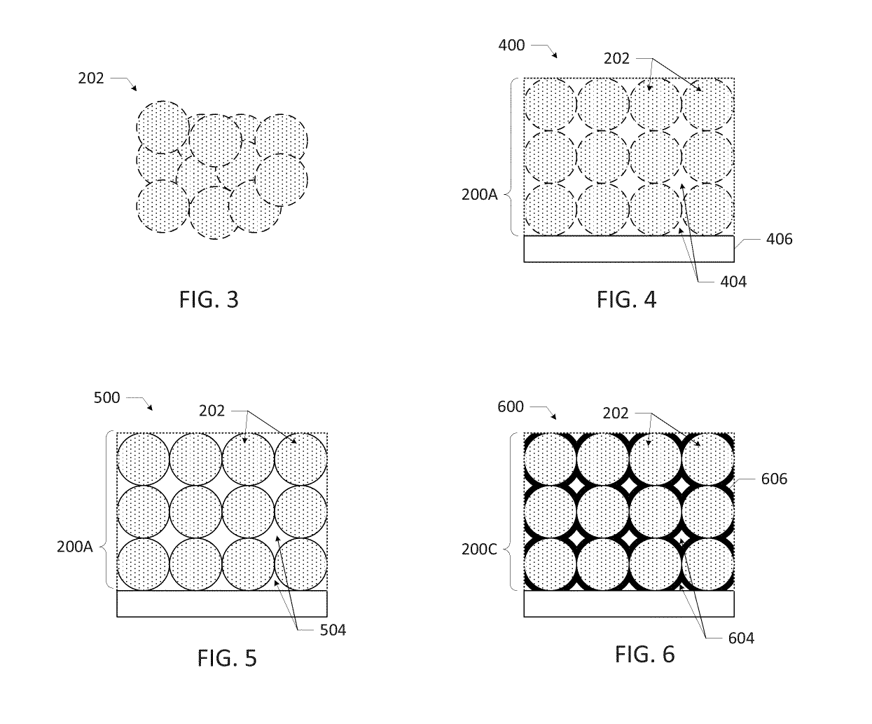

In some embodiments, the dielectric material may be arranged in a structure inverse to a structure comprising a nanostructure coated in an additional material layer. The nanostructure may be, for example, a cubic- or hexagonally packed array of nanospheres or nanospheroids. FIG. 1C illustrates an example cross-sectional view of an arrangement inverse to a cubic-packed array of nanospheres coated with an additional layer of material (e.g., as discussed below with reference to FIG. 2C). The thickness of the additional layer of material may be selected and applied to adjust the size of the pores 112 of the dielectric layer 100 and thereby tune the porosity of the dielectric layer 100. The arrangement of the pores 112 in the dielectric material 130 may be constrained or dictated by the selection of fabrication techniques used to form the dielectric layer 100 (e.g., as discussed below with reference to FIGS. 3-9).

In some embodiments, the porosity of the dielectric layer 100 may be between 50% and 80%. As used herein, the “porosity” of a material may be defined as the fraction (or percentage) of the volume of voids in the material over the total volume. For example, a cube of material having outer dimensions of 10 centimeters by 10 centimeters by 10 centimeters may have a porosity of 12.5% if the material included a 5 centimeters by 5 centimeters by 5 centimeters cubic void. The porosity of the dielectric layer 100 may be greater than approximately 50%. In some embodiments, the porosity of the dielectric layer 100 may be greater than approximately 60%. In some embodiments, the porosity of the dielectric layer 100 may be between 60% and 80%. In some embodiments, the porosity of the dielectric layer 100 may be between 50% and 75%.

The ability of the dielectric layer 100 to withstand compressive and tensile forces may be related to the material properties of the dielectric material 130, the porosity of the dielectric layer 100, and the nanostructure arrangement of the pores 112. In some embodiments, the dielectric material 130 may include cross-linked organosilane or cross-linked carbosiloxane molecular units. In some embodiments, the porosity of the dielectric layer 100 may be between 50% and 75%, and the dielectric layer 100 may have a Young's modulus greater than or equal to approximately 3 gigapascals in the direction defined by any of the principal axes of the dielectric layer 100. In some embodiments, the dielectric layer may have a porosity of approximately 50% and a Young's modulus greater than or equal to approximately 5 gigapascals. Some embodiments of the dielectric layers disclosed herein may exhibit Young's moduli of approximately 10, 5 and 3 gigapascals at porosities of approximately 52%, 64% and 73%, respectively. A number of additional/alternative properties and advantages of various embodiments of the dielectric layers disclosed herein are discussed below.

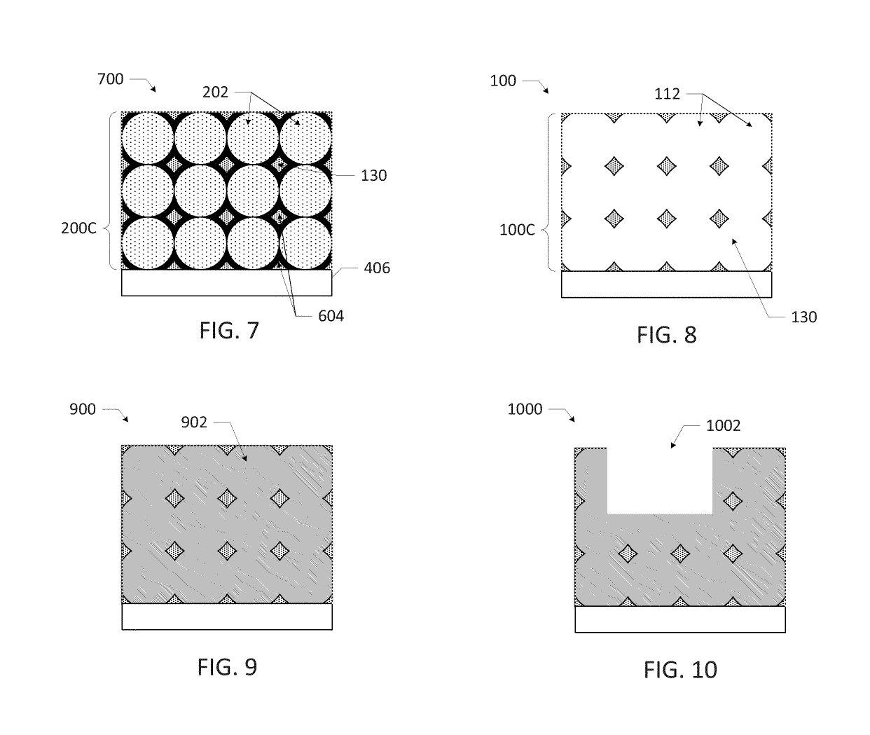

FIGS. 2A-2E are cross-sectional views of portions of templates 200 for fabricating various embodiments of a dielectric layer, in accordance with some embodiments. Each of the templates 200 of FIGS. 2A-2E includes a plurality of nanoparticles 202 arranged in a nanostructure arrangement (the arrangements 200A-200E, respectively). Each of the templates 200 also includes a plurality of voids 204, which correspond to the areas of dielectric material 130 in the corresponding dielectric layers 100 when the templates 200 are used as templates for the generation of an inversely structured dielectric layer. The arrangement 200C of FIG. 2C includes both an arrangement of a plurality of nanoparticles 202 and an additional material 206 deposited on the arrangement 200A of FIG. 2A to form the template 200 of FIG. 2C. The deposition of this additional material 206 may reduce the size of the voids 204 of the arrangement 200C relative to the arrangement 200A. Consequently, dielectric layers having a structure inverse to the arrangement 200C may have porosities that are tuned by the selection of a particular amount (e.g., thickness of the deposition layer) for the additional material 206. Embodiments including additional material are discussed below (e.g., with reference to FIGS. 6 and 7).

The dielectric constant of the dielectric layer 100 may be related to the dielectric constant of the dielectric material 130. In particular, when the dielectric material 130 (prior to formation of the pores 112) has a dielectric constant equal to κ0, and when the porosity of the dielectric layer 100 (due to the pores 112) is p, the dielectric constant of the dielectric layer 100, κ, may be less than or equal to κ0(1−p). The dielectric constant κ may depend on the structure of the pores 112. As dielectric materials having various dielectric constants are identified and developed, the techniques disclosed herein may be applied to fabricate dielectric layers having dielectric constants that scale with the porosity.

FIGS. 3-12 illustrate various stages in an illustrative process for fabrication of a dielectric layer, in accordance with some embodiments. For illustrative purposes, the assemblies depicted as part of various fabrication stages illustrated in FIGS. 3-12 are described with reference to the fabrication of the dielectric layers 100 of FIGS. 1A-1E, but such stages may be applied as suitable to fabricate any of the dielectric layer embodiments described herein. The particular processes illustrated herein for fabrication of a dielectric layer are not exclusive, and any suitable process may be used to fabricate the dielectric layers disclosed herein. Additionally, particular inverse nanostructure arrangements and templates may be illustrated in FIGS. 3-12 for ease of discussion, but the fabrication operations discussed with reference to FIGS. 3-12 may be used to fabricate dielectric layers using any suitable arrangements and templates disclosed herein.

Referring to FIG. 3, a plurality of nanoparticles 202 are provided. The plurality of nanoparticles may be used to form a template for the fabrication of the dielectric layer 100, and may include any suitable size, shape and type of material for the particular inverse nanostructure arrangement desired for the dielectric layer 100. For example, the nanoparticles 202 may include silica, titanium nitride, titanium dioxide, cadmium sulfide, hafnium oxide, aluminum oxide, fullerenes (“bucky balls”), and/or any other suitable oxide, nitride, phosphide, carbide, sulfide, chalcogenide, semiconductor or metal. In some embodiments, the nanoparticles 202 may include commercially available nanoparticles having diameters of 1 nanometer and larger. In some embodiments, the nanoparticles 202 may be fabricated in accordance with any known technique for generating nanoparticles with a low size tolerance. In some embodiments, small organic or inorganic ligands may be used to stabilize a dispersion of the nanoparticles 202. Various types of stabilizing ligands may be used, including thiols, phosphine oxides, phosphines, phosphonic acids, amines, ethers, pyridines, carbenes, chlorosilanes, and alkoxylsilanes, among others. These ligands may be selected so as to not interfere with the organization of the nanoparticles into a desired nanostructure arrangement (as discussed below).

Referring to FIG. 4, an assembly 400 is depicted subsequent to arranging the plurality of nanoparticles 202 (FIG. 3) in the nanostructure arrangement 200A (FIG. 2A) on a substrate 406. As used herein, a “substrate” may refer to a base substrate material on which a dielectric layer may be disposed (e.g., a silicon wafer on which an IC die is disposed) and/or any layer or stack of dielectric or other layers upon which a dielectric layer may be disposed (e.g., a metallization layer in an ILD stack). The nanostructure arrangement of the nanoparticles 202 in the assembly 400 may be any desired and achievable arrangement. The assembly 400 may be formed using any known technique for arranging nanoparticles into a desired arrangement, such as evaporation-induced self-assembly, spin coating a suspension of nanoparticles in solution, drop-casting, dip-coating with controlled removal rate from a suspension of nanoparticles in solution, Langmuir Blodgett trough deposition, and/or flow packing, for example. Any such technique may be combined with a solvent anneal and/or agitation to help move the nanoparticles 202 into a desired ordered geometry. The nanoparticles 202 may pack together in such a way to generate voids 404 in the assembly 400.

Referring to FIG. 5, a template 500 is shown subsequent to sintering and/or cross-linking the nanoparticles 202 of the assembly 400 to form a solid network. The template 500 may be formed via a sintering anneal, a chemical wash or vitrification, or any other known technique. The nanoparticles 202 may be packed and sintered (or cross-linked) in such a way to generate voids 504 in the template 500.

Referring to FIG. 6, a template 600 is shown subsequent to depositing additional material 606 on the nanoparticles 202 of the template 500. The additional material 606 may be the same material used for the nanoparticles 202, or a different material capable of coating the nanoparticles 202 of the template 500. Any of a number of known techniques may be used to deposit the additional material 606 on the template 500, such as atomic and/or molecular layer deposition, spin coating a solution containing a reactant, or dip coating with controlled removal rate from a suspension containing a reactant. In some embodiments, the effect of depositing the additional material 606 may be to reduce the size of the voids 604 of the template 600 relative to the voids 504 of the template 500, as if the nanoparticles 202 had a larger diameter than their actual diameter and were packed in an “overlapping” manner. In some embodiments, the provision of a suitable additional material 606 on the nanoparticles 202 may facilitate infiltration of the dielectric material 130 into the template 600 (e.g., as discussed below with reference to FIG. 7). The resulting nanostructure arrangement of the template 600 is the nanostructure arrangement 200C of FIG. 2C. In some embodiments, no additional material is deposited on an initial template (e.g., the template 500) after the template is sintered and/or cross-linked, and thus the operation depicted in FIG. 6 may not be performed. Although one additional material 606 is illustrated in FIG. 6, more additional materials may be applied to a template, and the techniques disclosed herein may be extended or modified naturally to include these additional materials.

Referring to FIG. 7, an assembly 700 is shown subsequent to the provision of a dielectric material 130 in the voids 604 of the template 600. The dielectric material 130 may substantially fill the voids 604 of the template 600. In some embodiments, the dielectric material 130 may include silicon dioxide, carbon-doped silicon dioxide, carbon-doped oxide dielectrics (generally referred to as SiCOH), silicon carbide materials, oxygen-doped silicon carbide materials, carbosilane materials, carbosiloxane materials, silicon nitride materials, carbon doped silicon nitride materials, oxygen doped silicon nitride materials, highly cross-linked hydrocarbon materials, fluorine doped hydrocarbons materials, fluorine doped silicon oxide materials, or pure carbon, for example. The dielectric material 130 may be provided to the voids 604 of the template 600 in any of a number of ways. For example, the dielectric material 130 may be provided using a vapor phase molecular layer deposition technique using carbosilane, carbosiloxane, volatile silicon precursors, ammonia, or ammine precursors. In another example, the dielectric material 130 may be provided by infiltrating the template 600 with a liquid solution containing similar precursors. In another example, part of the dielectric material 130 may be provided as stabilizing ligands on the surfaces of the nanoparticles 202. In such embodiments, typical ligands described above may be used where the ligand tail (not bonded to an individual one of the nanoparticles 202) contains precursors to the dielectric material 130, such as alkoxysilanes, hydrosilanes, aminosilanes and other species. These tail groups may facilitate attachment of the dielectric material 130 during infiltration into the template 600, and/or may be cross-linked by a number of methods further into fabrication (e.g., via an acid, base, thermal, or photochemical cross-linking technique). Cross-linking may also be initiated through introduction of another molecule designed to react with the tail group. In such embodiments, the dielectric material provided by stabilizing ligands may provide all or some of the dielectric material 130, with the remaining dielectric material 130 provided using another technique.

After provision in the voids 604 of the template 600, the dielectric material 130 may be cross-linked to provide the assembly 700. Cross-linking the dielectric material 130 may include applying a series of bakes; performing a bake with additional application of a flux of electrons (e-beam) or photons of ultraviolet and/or infrared wavelength; performing a photochemical cross-linking through co-incorporation of photo-acid, photo-Lewis acid, photo-base and photo-radical generators, followed by photoactivation of these groups; or any other suitable technique. In embodiments in which the dielectric material 130 is introduced as an oligomer, additional known cross-linking additives may be provided to the voids 604 of the template 600 to cause the cross-linking of the dielectric material 130. For example, cross-linking additives based on siloxanes, aminosilanes, or hydrosilanes, among others, may be added with or without a catalyst to initiate growth of the dielectric material 130 at the surface and in the pores of the template 600. For example, in embodiments in which the dielectric material 130 is added to the template 600 by spin coating a liquid containing oligomers of dielectric materials and other latent cross-linking additives, the cross-linking additives may be activated through exposure to heat and/or light and may begin to chemically cross-link the dielectric material oligomers into a solid film around the template 600.

Referring to FIG. 8, the dielectric layer 100 is depicted subsequent to removing the template 600 and the additional material 606 from the assembly 700. In some embodiments, as discussed below, the additional material 606 may not be removed, and may be included in the dielectric layer 100. In some embodiments, the template 600 may be removed by HF. As discussed above with reference to FIGS. 1A-1 E, the dielectric layer 100 may include the dielectric material 130 arranged in the inverse nanostructure arrangement 100C (inverse to the nanostructure arrangement 200C of the template 600).

The template 600 may be removed using any suitable process, such as a selective wet etch, ash, or dry etch. In embodiments in which the template 600 includes silica, and the dielectric material 130 includes a sufficiently high carbon content, the template 600 may be removed from the assembly 1000 using a hydrogen fluoride wet etch without damaging the dielectric layer 100. A less aggressive wet etch (e.g., a peroxide-based wet etch) may be used if the template 600 is formed from a material that is etchable by the less aggressive wet etch (e.g., titanium nitride and/or titanium dioxide). In embodiments in which a template includes a base template and additional material deposited on the base template, multiple removal steps may be performed to remove the additional material and the base template, depending upon the chemical compositions of the additional material and the base template.

In some embodiments, prior to patterning and/or metallization, the template 600 may be removed and replaced with a fill material. Referring to FIG. 9, the assembly 900 is depicted subsequent to providing a fill material 902 to replace the template 600 in the dielectric layer 100. Replacing the template 600 with the fill material 902 may be advantageous when the material of the template 600 is difficult to remove after metallization, but provides a desired template for the formation of the dielectric layer 100. The fill material 902 may not provide the desired template (as provided by the template 600), but may provide additional strength and/or reduced porosity (and thereby lower chemical diffusion) to allow metallization and subsequent removal without destroying the metal or the dielectric layer 100. For example, in some embodiments, the template 600 may be formed from silica nanoparticles that are removed by HF before metallization (FIG. 8), then the voids left after removal of the template 600 may be filled with a fill material 902 such as a hydrocarbon polymer and/or a refractory material (e.g., TiN, TiO2, or other) prior to metallization. These fill materials 902 may be more readily and/or selectively removed in the presence of metal than the material of the template 600. After patterning and/or metallization, the fill material 902 may be removed.

In some embodiments, the fill material 902 may be a polymer such as PMMA, polystyrene or polybutadiene, or a refractory material. Filling the pores 112 with the fill material 902 during patterning and metal fill may support controlled etching and/or fill by making the dielectric layer 100 mechanically stronger and/or more chemically inert (by blocking infiltration of chemicals and/or metal deposition precursors into the pores 112). This process may be referred to as “pore-stuffing.” The fill material may be removed after patterning, metal deposition, or metal polish, in various embodiments, as discussed below. For example, highly porous films may undergo mechanical stress during hardmask or barrier deposition processes (e.g., deposition of tantalum nitride/tantalum (TNT), a dual layer material that blocks copper diffusion), and thus in some embodiments, the fill material 902 may be removed after chemical-mechanical polishing (e.g., when the dielectric layer 100 is exposed between patterned metal lines). Polymer fill materials may be removed by an ashing process using a hydrogen-based plasma, or thermally decomposed, for example. More refractory materials, such as silicon dioxide, titanium dioxide and titanium nitride, may be removed using a chemical wet etch selected to avoid oxidizing or damaging any metal lines or other components.

Referring to FIG. 10, an assembly 1000 is depicted subsequent to a patterning operation applied to the assembly 900. In particular, a trench 1002 is shown as formed in the assembly 1000. In some embodiments, the assembly 1000 may be patterned with any standard trench and via patterning techniques known in the art. For example, one or more additional hardmasks can be used, followed by spin-expose and development of a resist. Hardmask etch, trench patterning and hardmask removal and clean procedures may follow. Similar steps can be followed to pattern vias in the assembly 1000, if desired. Dual damascene or other related, conventional processing techniques may also be performed.

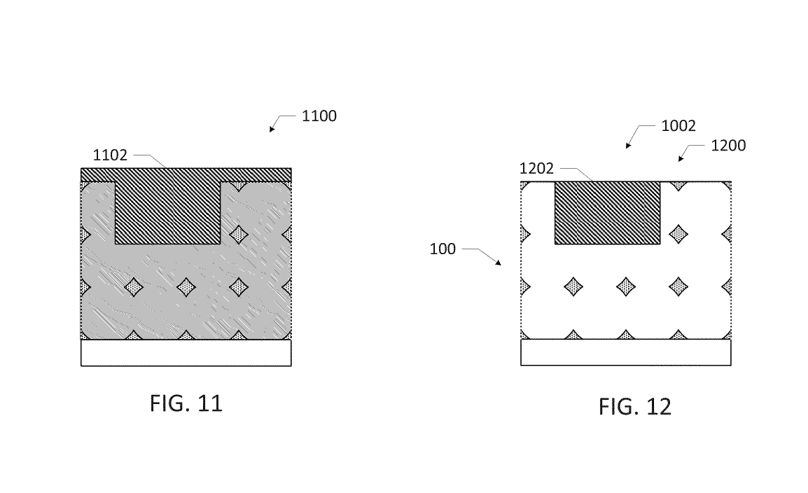

Referring to FIG. 11, the assembly 1100 is depicted subsequent to a metallization operation applied to the assembly 1000. In particular, a metal 1102 may be disposed in the trench 1002 and on a surface of the assembly 1000. In some embodiments, a tantalum nitride/tantalum composition (or other material) may be deposited as a barrier using physical vapor deposition, followed by the deposition of a thin physical vapor deposition metal seed layer, followed by electroplating to fill up the trench 1002 with the metal 1102. The metal may be copper, aluminum or another metal, for example. In some embodiments, the metal 1002 may be electroplated several microns above the assembly 1000. Additional barrier or liner materials (not shown) may also be present above the assembly 1000.

Referring to FIG. 12, an assembly 1200 is depicted subsequent to a chemical mechanical polish to remove any overburden of the metal 1102 formed during electroplating (e.g., to isolate metal lines), as well as subsequent to removing the fill material 902 (which may include removal of the additional material 606, as discussed elsewhere herein) from the assembly 1100 to form a dielectric layer 100 with the remaining metal 1202 in the trench 1002. The fill material 902 may be removed after the chemical mechanical polish and related operations. As discussed above with reference to FIGS. 1A-1E, the dielectric layer 100 may include the dielectric material 130 arranged in the inverse nanostructure arrangement 100C (inverse to the nanostructure arrangement 200C of the template 600).

In some embodiments, patterning and/or metallization operations may take place after the template 600 is removed, instead of or in addition to such operations that take place prior to removal of the template 600. In some embodiments, patterning and/or metallization operations may take place prior to removal of the template 600; in some such embodiments, no fill material 902 may be used to replace the template 600. In some embodiments, no patterning or metallization operations may occur.

In some embodiments, the additional material 606 may not be removed during removal of the template 600. Instead, the additional material may be included in the dielectric layer 100. in some embodiments, including the additional material 606 in the dielectric layer 100 may increase the strength of the dielectric layer 100. Any additional material 606 added to the template 600 to facilitate infiltration of the dielectric material 130 may or may not be removed.

Various ones of the fabrication operations and stages represented in FIGS. 3-12 may be omitted or repeated as desired in the manufacture of an IC or other device. For example, a first dielectric layer may be built on a silicon substrate in accordance with the fabrication techniques of FIGS. 3-12, and one or more additional dielectric layers may be formed on top of this dielectric layer and/or metal or other layers formed there between by repeating one or more of the operations illustrated in FIGS. 3-12.

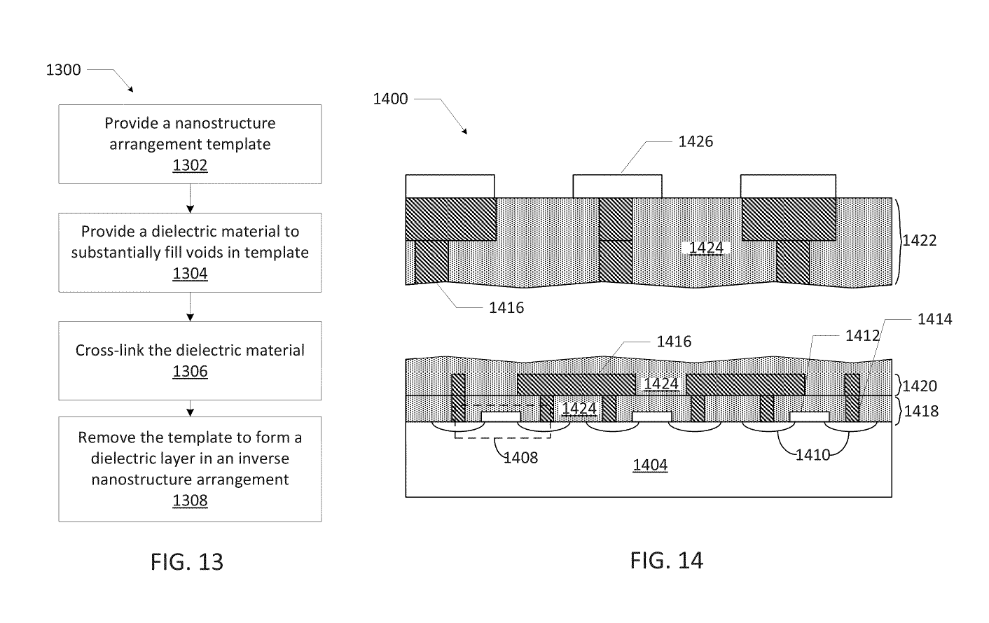

FIG. 13 is a flow diagram of a method 1300 of fabricating a dielectric layer, in accordance with some embodiments. The operations of the method 1300 may be illustrated with reference to the dielectric layer 100 and the fabrication operations discussed above with reference to FIGS. 3-12 for illustrative purposes, but the method 1300 may be used to form any appropriate dielectric layer. Various operations are described herein as multiple discrete operations for ease of illustration. However, the order of description should not be construed as to imply that these operations are necessarily order dependent, or need be separated into discrete operations.

At the operation 1302, a template may be provided. The template may include a plurality of nanoparticles arranged in a nanostructure arrangement, and may be provided on a substrate. For example, the template 600 may be provided on the substrate 406 (FIG. 6). In some embodiments, providing the template at the operation 1302 may include arranging a plurality of nanoparticles in a nanostructure arrangement and depositing template material on the arrangement to form the template. For example, additional material 606 may be deposited on the template 500 to form the template 600 (FIGS. 5 and 6). In some embodiments, the additional material may be a same material as a material used in the nanostructure arrangement on which the additional material is deposited. Additional material may be deposited by, e.g., molecular layer deposition.

At the operation 1304, a dielectric material may be provided to substantially fill voids in the template. For example, the dielectric material 130 may be provided to the voids 604 of the template 600 to substantially fill the voids 604 (FIG. 7). In some embodiments, the dielectric material may be provided at the operation 1304 via a molecular layer deposition reaction. In some embodiments, the dielectric material may be provided at the operation 1304 by introducing the dielectric material as stabilizing ligands on the surface of the template. In some embodiments, the dielectric material may be provided at the operation 1304 by infiltration of a solution containing oligomeric precursors on the surface of the template. In some embodiments the liquid solution containing oliogmetic precursors may also contain crosslinking additives.

At the operation 1306, the dielectric material may be cross-linked. For example, the dielectric material 130, subsequent to provision in the voids 604 of the template 600, may be cross-linked (e.g., using a series of bakes or a photochemical process) (FIG. 7).

At the operation 1308, the template may be removed to form a dielectric layer. The dielectric layer may include the dielectric material arranged in a structure inverse to the nanostructure arrangement of the template. For example, the template 600 may be removed from the assembly 700 to form the dielectric layer 100 (FIG. 8).

The method 1300 may include one or more additional operations in various embodiments. In some embodiments, the method 1300 may further include replacing the template with a fill material (e.g., as discussed above with reference to FIGS. 8 and 9), and/or patterning and/or metallization (as discussed above with reference to FIGS. 10-12). The patterning and/or metallization may occur prior or subsequent to the removal of the template at the operation 1308.

Various embodiments of the dielectric layers disclosed herein may provide one or more advantages over conventional dielectric materials. In particular, embodiments of the dielectric layers disclosed herein may achieve dielectric constants less than 2.0. In particular, some of the dielectric layers disclosed herein may have a dielectric constant between approximately 1.4 (for porosities approximately equal to 75%) and approximately 1.6 (for porosities approximately equal to 60%). Some of the dielectric layers disclosed herein may have a dielectric constant between approximately 1.6 and 2.0. This performance represents a substantial improvement over baseline polysilicate materials (having a dielectric constant of approximately 3.5) and the random void materials discussed below (typically having dielectric constants greater than 2.0). The low dielectric constants of various ones of the embodiments disclosed herein may reduce the capacitance of the dielectric layer within an IC device, reducing the signal delay caused by resistive-capacitive effects and thereby improving electrical performance.

Additionally, various embodiments may achieve a mechanical stiffness (represented, e.g., by the Young's modulus of the dielectric layer in one or more directions) that is greater than the mechanical stiffness of existing dielectric thin films having comparable or greater dielectric constants. These existing films are typically formed by randomly mixing a backbone precursor material (e.g., an organosilane or carbosilane) with a porogen material (e.g., a hydrocarbon). These materials may be formed into a matrix, and the porogen material may be selectively burned or etched out of the matrix to form a porous material with substantially randomly distributed voids. The porosity of the resulting material is a function of the loading volume of the porogen material (i.e., the volume of the matrix occupied by porogen material), and thus porosity may be increased by increasing the relative amount of porogen. However, at high loading volumes, the matrix will no longer include a continuous interconnected network of backbone material, and thus, upon burn out of the porogen, the material will collapse. Experimentally, the maximum achievable porosity using this approach may be approximately 50%-60%. At porosities close to this maximum, materials produced using such conventional approaches have mechanical strengths that are too low to withstand the tensile and compressive forces typically encountered in IC fabrication operations (e.g., during back end of line processing and assembly) and thus may mechanically fail.

By contrast, in various ones of the embodiments disclosed herein, the introduction of ordering to the pores of a dielectric material (e.g., by alignment of the pores of the dielectric layer with the locations of nanoparticles in a nanostructure arrangement) may allow porosities greater than the 50%-60% achievable using existing approaches, with improved mechanical performance. In particular, the dielectric layers having ordered pores may have a substantially improved mechanical stiffness in one or more directions (e.g., those directions corresponding to “pillars” of dielectric material). For example, some cubic-packed arrangements of pores in the dielectric layers disclosed herein may exhibit Young's moduli of approximately 10 gigapascals and 5 gigapascals at porosities of approximately 52% and 64%, respectively, and some hexagonally packed arrangements of pores in the dielectric layers disclosed herein may exhibit Young's moduli of approximately 3 gigapascals at a porosity of approximately 73%. Existing dielectric materials with randomly distributed voids (e.g., those generated using conventional plasma-enhanced chemical vapor deposition) may be substantially isotropic, and may exhibit Young's moduli of approximately 11, 9, 7 and 5 gigapascals at porosities of approximately 5%, 12%, 30% and 42%, respectively.

The use of an inverse nanostructure arrangement for the dielectric layer 100 may provide particular mechanical advantages over the use of certain nanostructure arrangements. For example, cubic-packed nanostructures (such as the arrangement 200A of FIG. 2A) include single points of contact between adjacent nanoparticles. When a force is applied to such an arrangement, stress may be concentrated at these points of contact, which may cause the arrangement to deform and fail. However, the inverse nanostructure arrangement, which has the same porosity and hence a similar dielectric constant, may provide structures more conducive to the transmission of forces without failure. For example, a dielectric layer having the arrangement 100A of FIG. 1A may include “pillars” of the dielectric material 130 in multiple directions, which may provide improved stiffness and reliability along the axes of the pillars to the dielectric layer 100 as compared with a counterpart having the arrangement 200A of FIG. 2A. Different arrangements for the pores 112 of the dielectric layer 100 may result in different mechanical properties for the dielectric layer 100. For example, arrangements in which the dielectric material 130 is arranged in one or more linear longitudinal arrangements (e.g., the “pillars” that may be seen in an inverse of a cubic-packed nanoparticle arrangement) may have higher rigidity than helical or other arrangements (which may arise, e.g., in an inverse of a hexagonally packed nanoparticle arrangement, and which may act more like a spring). The inverse of a hexagonally packed nanoparticle arrangement may also include linear arrangements of the dielectric material 130, along with the helical arrangements. Thus, the inverse nanostructure arrangement for the dielectric layer 100 may be selected to achieve a desired mechanical profile for the dielectric layer 100.

Some of the dielectric layers disclosed herein may be thermally stable and chemically resistive, increasing their manufacturability and performance characteristics over conventional materials. For example, the dielectric material 130 may be chosen to have particular thermal and/or chemical properties (e.g., resistance to hydrofluoric acid), which may then be “inherited” when the dielectric layer 100 is formed from the dielectric material 130. Various ones of the dielectric layers described herein may thus achieve the continued scaling of metallization pitch and capacitance while retaining acceptable mechanical performance. Some embodiments of the dielectric layers disclosed herein may be mechanically isotropic (in that their mechanical characteristics are similar along a number of different axes), which may be beneficial for applications in which the dielectric layer 100 must withstand forces applied from multiple directions.

As discussed above, some embodiments of processes for fabricating the dielectric layers disclosed herein may include generating a nanostructure arrangement to act as a template for fabricating a dielectric layer having a structure inverse to the template. Many techniques used for generating such nanostructure arrangements (e.g., generating a cubic-packed or hexagonally packed arrangement) are prone to errors in assembly (e.g., misaligned or otherwise “missing” nanoparticles in an otherwise regular nanostructure). These imperfections have impeded the adoption of nanostructure arrangements in many manufacturing processes in which tolerance to these errors is small (e.g., in the development of waveguides). However, the use of such techniques in the fabrication of the dielectric layers disclosed herein is relatively insensitive to errors in the pattern (resulting in, e.g., the absence or irregular positioning of a small number of pores), as long as the bulk characteristics of the resulting dielectric layer are as desired. Thus, the fabrication processes disclosed herein involving templates with nanostructure arrangements may take advantage of the strengths of nanostructure generation techniques while being advantageously less sensitive to the errors typical to such techniques. The regularity of the pattern of the pores 112 in the dielectric layer 100 may be short-range (e.g., over a distance corresponding to approximately 1-5 pores), medium-range (e.g., over a distance corresponding to approximately 5-50 pores) or long-range (e.g., over a distance corresponding to greater than approximately 50 pores). In some embodiments, the arrangement of the pores 112 may be regular within one or more separate regions, but the arrangements may be different between the two regions, or oriented differently within the two regions (e.g., rotated by a certain amount). The arrangement of the pores 112 in the dielectric layer 100 may be constrained by the fabrication techniques used to form the dielectric layer 100.

Moreover, as compared with waveguide applications, the nanostructure arrangements of some of the dielectric layers described herein have features on a smaller scale. For example, some materials used in waveguide applications may utilize nanostructure arrangements having nanospheres of silicon dioxide on the order of 50 to 500 nanometers. In various embodiments of the dielectric layers disclosed herein, the pores may have dimensions of approximately 30 to approximately 50 nanometers. In various embodiments of the dielectric layers disclosed herein, the pores may have dimensions of approximately 3 to approximately 30 nanometers.

The dielectric layers disclosed herein may be incorporated into any suitable application in IC or other devices. For example, the dielectric layers disclosed herein may be used as a thin film in metal oxide semiconductor (MOS) or complementary metal oxide semiconductor (CMOS) devices. Moreover, the dielectric layers may be oriented in a device such that the axis along which the dielectric layers have the greatest mechanical stiffness is aligned with the direction in which the greatest mechanical stresses are expected to be exerted. For example, in some manufacturing processes, the largest mechanical stresses encountered by an ILD may be in the vertical direction (e.g., from stresses induced during die/package assembly from mismatches in the coefficient of thermal expansion (CTE) of various layers); in such manufacturing processes, the ILD may be formed as one of the dielectric layers disclosed herein, with the “pillars” of dielectric material arranged in the vertical direction.

FIG. 14 is a cross-sectional view of a portion of an IC device 1400 including a dielectric layer 1424 (which may serve as an ILD), in accordance with some embodiments. The dielectric layer 1424 of the IC device 1400 may be arranged in an ILD stack having conductive interconnect structures 1416 to route electrical signals within the IC device 1400, as discussed below. The dielectric layer 1424 may be disposed between the conductive interconnect structures 1416 and a substrate 1404, and may include any of the dielectric layers described herein (e.g., those described with reference to the dielectric layer 100).

The IC device 1400 may be formed on a substrate 1404 (which may include, e.g., a silicon wafer). The substrate 1404 may be a semiconductor substrate composed of semiconductor material systems including, for example, N-type or P-type materials systems. The substrate 1404 may include, for example, a crystalline substrate formed using a bulk silicon or a silicon-on-insulator substructure, and may serve as the substrate 406 of FIG. 4. Although a few examples of materials from which the substrate 1404 may be formed are described here, any material that may serve as a foundation upon which the IC device 1400 may be used in accordance with various embodiments.

In some embodiments, the IC device 1400 includes a device layer 1418 disposed on the substrate 1404. The device layer 1418 may include features of one or more transistors 1408 formed on the substrate 1404. The device layer 1418 may include, for example, one or more source and/or drain (S/D) 1410, a gate 1412 to control current flow in the transistor(s) 1408 between the S/D regions 1410, and one or more S/D contacts 1414 to route electrical signals to/from the S/D regions 1410. The transistor(s) 1408 may include additional features not depicted for the sake of clarity such as device isolation regions, gate contacts, and the like. The transistor(s) 1408 are not limited to the type and configuration depicted in FIG. 14 and may include a wide variety of other types and configurations such as, for example, planar and non-planar transistors such as dual- or double-gate transistors, tri-gate transistors, and all-around gate (AAG) or wrap-around gate transistors, some of which may be referred to as FinFETs (Field Effect Transistors). In some embodiments, the device layer 1418 includes one or more transistors or memory cells of a logic device or a memory device, or combinations thereof.

Electrical signals such as, for example, power and/or input/output (I/O) signals may be routed to and/or from the transistor(s) 1408 of the device layer 1418 through one or more interconnect layers 1420 and 1422 disposed on the device layer 1418. For example, electrically conductive features of the device layer 1418 such as, for example, the gate 1412 and S/D contacts 1414 may be electrically coupled with the interconnect structures 1416 of the interconnect layers 1420 and 1422. The one or more interconnect layers 1420 and 1422 may form an ILD stack of the IC device 1400. The interconnect structures 1416 may be configured within the interconnect layers 1420 and 1422 to route electrical signals according to a wide variety of designs and is not limited to the particular configuration of interconnect structures 1416 depicted in FIG.

For example, in some embodiments, the interconnect structures 1416 may include trench structures (sometimes referred to as “lines”) and/or via structures (sometimes referred to as “holes”) filled with an electrically conductive material such as a metal. In some embodiments, the interconnect structures 1416 may comprise copper or another suitable electrically conductive material.

The interconnect layers 1420 and 1422 may include the dielectric layer 1424 disposed between the interconnect structures 1416, as can be seen. Any of the layers or structures below a portion of the dielectric layer 1424 may serve as the substrate 406 of FIG. 4. The dielectric layer 1424 may include any one or more of the dielectric layers discussed herein (e.g., any of the embodiments of the dielectric layer 100). In some embodiments, the dielectric layer 1424 may include multiple different dielectric layers, some of which may comport with the dielectric layers discussed herein (e.g., the dielectric layer 100) and others of which may be conventional dielectric materials.

In some embodiments, a first interconnect layer 1420 (referred to as Metal 1 or “M1”) may be formed directly on the device layer 1418. In some embodiments, the first interconnect layer 1420 may include some of the interconnect structures 1416, which may be coupled with contacts (e.g., the S/D contacts 1414) of the device layer 1418.

Additional interconnect layers (not shown for ease of illustration) may be formed directly on the first interconnect layer 1420 and may include interconnect structures 1416 to couple with interconnect structures of the first interconnect layer 1420.

The IC device 1400 may have one or more bond pads 1426 formed on the interconnect layers 1420 and 1422. The bond pads 1426 may be electrically coupled with the interconnect structures 1416 and configured to route the electrical signals of transistor(s) 1408 to other external devices. For example, solder bonds may be formed on the one or more bond pads 1426 to mechanically and/or electrically couple a chip including the IC device 1400 with another component such as a circuit board. The IC device 1400 may have other alternative configurations to route the electrical signals from the interconnect layers 1420 and 1422 than depicted in other embodiments. In other embodiments, the bond pads 1426 may be replaced by or may further include other analogous features (e.g., posts) that route the electrical signals to other external components.

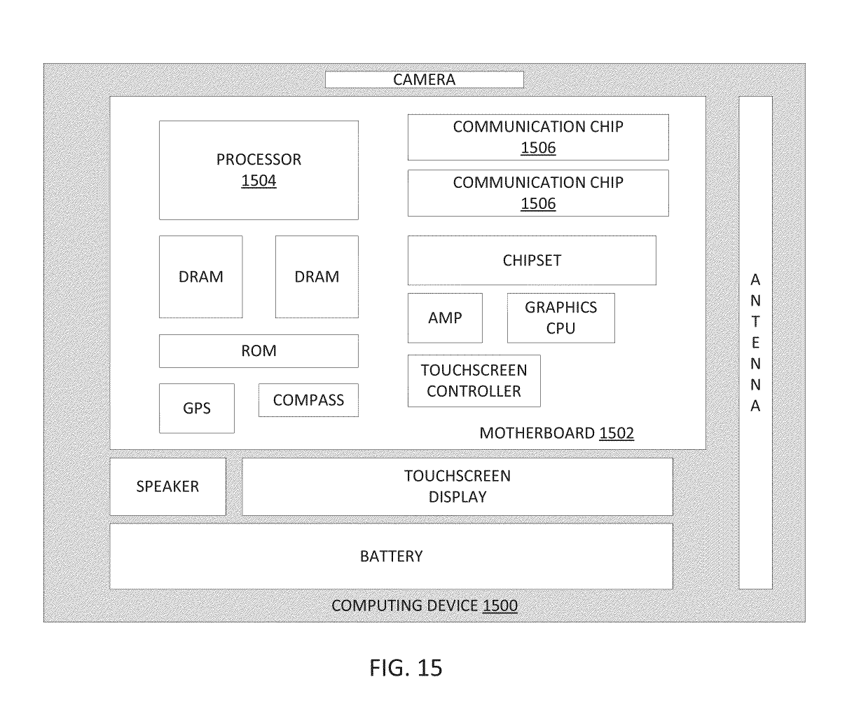

Embodiments of the present disclosure may be implemented into a system using any suitable hardware and/or software to configure as desired. FIG. 15 schematically illustrates a computing device 1500 in accordance with one implementation. In some embodiments, a dielectric layer as disclosed herein may be used as a dielectric (e.g., an ILD) in one or more components of computing device 1500.

The computing device 1500 may house a board such as motherboard 1502. The motherboard 1502 may include a number of components, including but not limited to a processor 1504 and at least one communication chip 1506. The processor 1504 may be physically and electrically coupled to the motherboard 1502. In some implementations, the at least one communication chip 1506 may also be physically and electrically coupled to the motherboard 1502. In further implementations, the communication chip 1506 may be part of the processor 1504. The term “processor” may refer to any device or portion of a device that processes electronic data from registers and/or memory to transform that electronic data into other electronic data that may be stored in registers and/or memory.

Depending on its applications, computing device 1500 may include other components that may or may not be physically and electrically coupled to the motherboard 1502. These other components may include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth).

The communication chip 1506 may enable wireless communications for the transfer of data to and from the computing device 1500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1506 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible BWA networks are generally referred to as WiMAX networks, an acronym that stands for Worldwide Interoperability for Microwave Access, which is a certification mark for products that pass conformity and interoperability tests for the IEEE 802.16 standards. The communication chip 1506 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1506 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1506 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 1506 may operate in accordance with other wireless protocols in other embodiments.

The computing device 1500 may include a plurality of communication chips 1506. For instance, a first communication chip 1506 may be dedicated to shorter range wireless communications such as Wi-Fi and Bluetooth and a second communication chip 1506 may be dedicated to longer range wireless communications such as GPS, EDGE, GPRS, CDMA, WiMAX, LTE, Ev-DO, and others.

The communication chip 1506 may also include an IC package assembly that may include a dielectric layer as described herein. In further implementations, another component (e.g., memory device, processor or other integrated circuit device) housed within the computing device 1500 may contain an IC package assembly that may include a dielectric layer as described herein.

In various implementations, the computing device 1500 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 1500 may be any other electronic device that processes data. In some embodiments, the techniques described herein are implemented in a high-performance computing device. In some embodiments, the techniques described herein are implemented in handheld computing devices.

The following paragraphs describe illustrative embodiments of the present disclosure. Example 1 is a dielectric layer, including: a dielectric material and one or more pores, wherein the dielectric material is arranged in an inverse nanostructure arrangement around the pores.

Example 2 may include the subject matter of Example 1, and may further specify that the dielectric material includes cross-linked organosilane or cross-linked carbosiloxane materials.

Example 3 may include the subject matter of any of Examples 1-2, and may further specify that the dielectric layer has a porosity between approximately 50% and approximately 75%.

Example 4 may include the subject matter of any of Examples 1-3, and may further specify that the dielectric layer has a porosity of approximately 50% and a Young's modulus greater than 5 gigapascals.

Example 5 may include the subject matter of any of Examples 1-4, and may further specify that the inverse nanostructure arrangement is an inverse of a cubic-packed array of nanospheres.

Example 6 may include the subject matter of any of Examples 1-4, and may further specify that the inverse nanostructure arrangement is an inverse of a hexagonally packed array of nanospheres.

Example 7 may include the subject matter of any of Examples 1-4, and may further specify that each of the pores is shaped as a sphere.

Example 8 may include the subject matter of any of Examples 1-4, and may further specify that each of the pores is shaped as an oblate spheroid or a prolate spheroid.

Example 9 may include the subject matter of any of Examples 1-4, and may further specify that the dielectric material is arranged in a structure inverse to a structure including a cubic- or hexagonally packed array of nanospheres coated in an additional material layer.

Example 10 may include the subject matter of any of Examples 1-9, and may further specify that the dielectric layer has a dielectric constant of less than approximately 1.5.

Example 11 is a method of fabricating a dielectric layer, including: providing a template including a plurality of nanoparticles arranged in a nanostructure arrangement; providing a dielectric material to substantially fill voids in the template; cross-linking the dielectric material; and removing the template to form a dielectric layer including the dielectric material arranged in a structure inverse to the nanostructure arrangement of the template.

Example 12 may include the subject matter of Example 11, and may further specify that providing a template includes: providing the plurality of nanoparticles; and arranging the plurality of nanoparticles in a nanostructure arrangement by evaporation-induced self-assembly, spin coating, drop casting, dip coating, Langmuir Blodgett trough formation, or flow-cell packing.

Example 13 may include the subject matter of any of Examples 11-12, and may further specify that providing the dielectric material is performed by a molecular layer deposition reaction using carbosilane or carbosiloxane precursors.

Example 14 may include the subject matter of any of Examples 11-13, and may further specify that providing the dielectric material includes introducing the dielectric material as stabilizing ligands on the surface of the template.

Example 15 may include the subject matter of any of Examples 11-14, and may further include, after cross-linking the dielectric material and prior to removing the template, patterning and/or metallizing the cross-linked dielectric material.

Example 16 may include the subject matter of any of Examples 11-14, and may further include: after removing the template, providing a fill material in voids left by the template in the dielectric layer to form an intermediate assembly; patterning and/or metallizing the intermediate assembly; and removing the fill material to form a patterned and/or metallized dielectric layer.

Example 17 may include the subject matter of any of Examples 11-16, wherein providing a template includes: arranging a plurality of nanoparticles in a nanostructure arrangement; and depositing additional material on the arrangement of the plurality of nanoparticles to form the template.

Example 18 may include the subject matter of Example 17, and may specify that the additional material is a same material as the plurality of nanoparticles.

Example 19 may include the subject matter of Example 17, and may specify that the additional material is included in the dielectric layer.

Example 20 may include the subject matter of any of Examples 17-19, and may specify that depositing additional material is performed by molecular layer deposition or atomic layer deposition.

Example 21 is an integrated circuit, including: a substrate; conductive interconnects; and an interlayer dielectric disposed between the substrate and the conductive interconnects, the interlayer dielectric including a dielectric material and one or more pores, wherein the dielectric material is arranged in an inverse nanostructure arrangement around the pores.

Example 22 may include the subject matter of Example 21, and may further specify that the interlayer dielectric has a porosity of approximately 50% and a Young's modulus greater than 5 gigapascals.

Example 23 may include the subject matter of any of Examples 21-22, and may further specify that the dielectric material is arranged in a structure inverse to a structure including a cubic- or hexagonally packed array of nanospheres coated in an additional material layer.

Example 24 may include the subject matter of any of Examples 21-23, and may further specify that the interlayer dielectric includes a trench, and a portion of the conductive interconnects is disposed in the trench.

Example 25 may include the subject matter of any of Examples 24-24, and may further specify that the interlayer dielectric has a dielectric constant of less than approximately 2.0.

The description herein of illustrated implementations, including what is described in the Abstract, is not intended to be exhaustive or to limit the present disclosure to the precise forms disclosed. While specific implementations and examples are described herein for illustrative purposes, various equivalent modifications are possible within the scope of the disclosure, as those skilled in the relevant art will recognize. These modifications may be made to the disclosure in light of the above detailed description.

What is claimed is:

1. A dielectric layer, comprising:
a dielectric material; and
one or more pores;
wherein the dielectric material is arranged in an inverse nanostructure arrangement around the pores.

2. The dielectric layer of claim 1, wherein the dielectric material comprises cross-linked organosilane or cross-linked carbosiloxane materials.

3. The dielectric layer of claim 1, having a porosity between approximately 50% and approximately 75%.

4. The dielectric layer of claim 1, having a porosity of approximately 50% and a Young's modulus greater than 5 gigapascals.

5. The dielectric layer of claim 1, wherein the inverse nanostructure arrangement is an inverse of a cubic-packed array of nanospheres.

6. The dielectric layer of claim 1, wherein the inverse nanostructure arrangement is an inverse of a hexagonally packed array of nanospheres.

7. The dielectric layer of claim 1, wherein each of the pores is shaped as a sphere.

8. The dielectric layer of claim 1, wherein each of the pores is shaped as an oblate spheroid or a prolate spheroid.

9. The dielectric layer of claim 1, wherein the dielectric material is arranged in a structure inverse to a structure comprising a cubic- or hexagonally packed array of nanospheres coated in an additional material layer.

10. The dielectric layer of claim 1, having a dielectric constant of less than approximately 2.0.

11. A method of fabricating a dielectric layer, comprising:
providing a template comprising a plurality of nanoparticles arranged in a nanostructure arrangement;
providing a dielectric material to substantially fill voids in the template;
cross-linking the dielectric material; and
removing the template to form a dielectric layer comprising the dielectric material arranged in a structure inverse to the nanostructure arrangement of the template.

12. The method of claim 11, wherein providing a template comprises:
providing the plurality of nanoparticles; and
arranging the plurality of nanoparticles in a nanostructure arrangement by evaporation-induced self-assembly, spin coating, drop casting, dip coating, Langmuir Blodgett trough formation, or flow-cell packing.

13. The method of claim 11, wherein providing the dielectric material is performed by a molecular layer deposition reaction using carbosilane or carbosiloxane precursors.

14. The method of claim 11, wherein providing the dielectric material comprises introducing the dielectric material as stabilizing ligands on the surface of the template.

15. The method of claim 11, further comprising:
after cross-linking the dielectric material and prior to removing the template, patterning and/or metallizing the cross-linked dielectric material.

16. The method of claim 11, further comprising:
after removing the template, providing a fill material in voids left by the template in the dielectric layer to form an intermediate assembly;
patterning and/or metallizing the intermediate assembly; and
removing the fill material to form a patterned and/or metallized dielectric layer.

17. The method of claim 11, wherein providing a template comprises:
arranging a plurality of nanoparticles in a nanostructure arrangement; and
depositing additional material on the arrangement of the plurality of nanoparticles to form the template.

18. The method of claim 17, wherein the additional material is a same material as the plurality of nanoparticles.

19. The method of claim 17, wherein the additional material is included in the dielectric layer.

20. The method of claim 17, wherein depositing additional material is performed by molecular layer deposition or atomic layer deposition.

21. An integrated circuit, comprising:
a substrate;
conductive interconnects; and
an interlayer dielectric disposed between the substrate and the conductive interconnects, the interlayer dielectric comprising a dielectric material and one or more pores, wherein the dielectric material is arranged in an inverse nanostructure arrangement around the pores.

22. The integrated circuit of claim 21, wherein the interlayer dielectric has a porosity of approximately 50% and a Young's modulus greater than 5 gigapascals.

23. The integrated circuit of claim 21, wherein the dielectric material is arranged in a structure inverse to a structure comprising a cubic- or hexagonally packed array of nanospheres coated in an additional material layer.

24. The integrated circuit of claim 21, wherein the interlayer dielectric comprises a trench, and a portion of the conductive interconnects is disposed in the trench.

25. The integrated circuit of claim 21, wherein the interlayer dielectric has a dielectric constant of less than approximately 1.5.
